(19) United States
(12) Patent Application Publication
(10) Pub. No.: US 2016/0020376 A1
(43) Pub. Date: Jan. 21, 2016

(54) THERMOELECTRIC POWER GENERATION DEVICE AND THERMOELECTRIC POWER GENERATION METHOD

(71) Applicants: JFE STEEL CORPORATION, Tokyo (JP); KELK LTD., Hiratsuka-shi, Kanagawa (JP)

(72) Inventors: Takashi KUROKI, Tokyo (JP); Kazuhisa KABEYA, Tokyo (JP); Akio FUJIBAYASHI, Tokyo (JP); Hiromasa KAIBE, Kawasaki-shi (JP); Takeshi KAJIHARA, Hiratsuka-shi (JP); Kazuya MAKINO, Hiratsuka-shi (JP); Hirokuni HACHIUMA, Hiratsuka-shi (JP)

(73) Assignees: JFE STEEL CORPORATION, Tokyo (JP); KELK LTD., Hiratsuka-shi, Kanagawa (JP)

(21) Appl. No.: 14/772,966

(22) PCT Filed: Mar. 27, 2014
(86) PCT No.: PCT/JP2014/001807

§ 371 Date: Sep. 4, 2015

(30) Foreign Application Priority Data
Mar. 27, 2013 (JP) 2013-067158

(51) Int. Cl. H01L 35/32; H01L 35/30

(52) U.S. Cl. CPC H01L 35/32; H01L 35/30

(57) ABSTRACT

A thermoelectric power generation unit is installed to face a steel material, and installed depending on an output of the thermoelectric power generation unit. A thermoelectric power generation device including a thermoelectric power generation unit that converts heat energy which varies in release state into electric energy to recover the energy can thus be provided in a continuous casting line or slab continuous casting line in which a heat source flows.

### TECHNICAL FIELD

The disclosure relates to a thermoelectric power generation device that converts heat energy radiated from a steel material into electric energy to recover the energy, and a thermoelectric power generation method using the same.

### BACKGROUND

The Seebeck effect has long been known as a phenomenon in which a temperature difference between different types of conductors or semiconductors generates an electromotive force between the high temperature portion and the low temperature portion. The use of thermoelectric power generation elements based on such a property to directly convert heat into electric power has been known, too.

In recent years, for example, manufacturing facilities such as steel plants have been increasing their efforts to use energy previously disposed of as waste heat, e.g. heat energy radiated from a steel material, by power generation using the above-mentioned thermoelectric power generation elements.

As a method for using heat energy, for example, JP S59-198883 A (Patent Literature (PTL) 1) describes a method of placing a heat receiving device to face a high temperature object, and converting the heat energy of the high temperature object into electric energy to recover the energy.

JP S60-34084 A (PTL 2) describes a method of bringing a thermoelectric element module into contact with heat energy processed as waste heat, and converting the heat energy into electric energy to recover the energy.

### CITATION LIST

### Patent Literature

PTL 1: JP S59-198883 A

PTL 2: JP S60-34084 A

PTL 1 describes its applicability to a slab continuous casting line, but fails to take into consideration the variations of the heat source during operation, such as the temperature distribution of the slab in actual operation and the variations of the quantity of released heat (heat energy) due to the variations of the slab amount. PTL 2 has a problem in that, while the module needs to be fixed to the heat source, the module cannot be installed for a moving heat source as in a slab continuous casting line.

It could therefore be helpful to provide a thermoelectric power generation device including a thermoelectric power generation unit capable of stably converting generated heat energy into electric energy to recover the energy even in the case where the generation state of the heat source in operation varies in any of various manufacturing processes and particularly in a steel material manufacturing line such as a continuous casting line, a slab continuous casting line, etc. in which the heat source flows, and a thermoelectric power generation method using the same.

### SUMMARY

As a result of conducting intensive studies to solve the problems stated above, we discovered that high-efficiency thermoelectric power generation can be realized by effectively adjusting, for example, the distance between the heat source and the thermoelectric power generation unit depending on the heat energy release state, and developed a thermoelectric power generation device that enables efficient heat utilization especially in a steel material manufacturing line, together with a thermoelectric power generation method using the same. The disclosure is based on the aforementioned discoveries.

We thus provide the following.

1. A thermoelectric power generation device including a thermoelectric power generation unit that converts heat energy radiated from a steel material into electric energy, wherein the thermoelectric power generation unit is installed to face the steel material and depending on an output of the thermoelectric power generation unit.

2. The thermoelectric power generation device according to the foregoing 1, wherein the thermoelectric power generation unit is installed nearer the steel material in a low temperature portion with low output than in a high temperature portion with high output, depending on the output of the thermoelectric power generation unit.

3. The thermoelectric power generation device according to the foregoing 1 or 2, wherein one or more thermoelectric power generation modules or thermoelectric elements in the thermoelectric power generation unit are arranged more densely in a high temperature portion with high output than in a low temperature portion with low output, depending on the output of the thermoelectric power generation unit.

4. The thermoelectric power generation device according to any of the foregoing 1 to 3, including a heat reflector.

5. The thermoelectric power generation device according to any of the foregoing 1 to 4, wherein the thermoelectric power generation unit is installed further depending on at least one of a temperature of the thermoelectric power generation unit and a temperature of the steel material.

6. The thermoelectric power generation device according to any of the foregoing 1 to 5, including a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

7. The thermoelectric power generation device according to any of the foregoing 1 to 6, including a transporter for moving the thermoelectric power generation unit.

8. A thermoelectric power generation method of receiving heat of a steel material and performing thermoelectric power generation, using the thermoelectric power generation device according to any of the foregoing 1 to 7.

The thermoelectric power generation unit and the heat source (steel material) can be kept at, for example, a distance contributing to high power generation efficiency, thus improving the power generation efficiency. Hence, heat energy generated from a manufacturing line can be recovered at a high level as compared with the conventional techniques.

### BRIEF DESCRIPTION OF THE DRAWINGS

In the accompanying drawings:

FIG. 1 is a diagram illustrating an example of installation of a thermoelectric power generation device according to an embodiment;

FIG. 2 is a diagram illustrating another example of installation of a thermoelectric power generation device according to an embodiment;

FIG. 3 is a diagram illustrating another example of installation of a thermoelectric power generation device according to an embodiment;

FIG. 4 is a sectional diagram of a thermoelectric power generation unit according to an embodiment;

FIG. 5 is a diagram illustrating an installation position of a thermoelectric power generation device according to an embodiment;

FIG. 6 is a diagram illustrating another installation position of a thermoelectric power generation device according to an embodiment;

FIGS. 7(a) and (b) are each a diagram illustrating an example of installation in the case where a distance adjusting mechanism and a temperature sensor are attached to a thermoelectric power generation unit;

FIG. 8 is a graph illustrating the relationship between the distance between a steel material and a thermoelectric power generation unit and the power output ratio;

FIG. 9A is a sectional diagram illustrating an example of arrangement of thermoelectric power generation modules in a thermoelectric power generation unit according to an embodiment;

FIG. 9B is a sectional diagram illustrating another example of arrangement of thermoelectric power generation modules in a thermoelectric power generation unit according to an embodiment;

FIG. 9C is a sectional diagram illustrating another example of arrangement of thermoelectric power generation modules in a thermoelectric power generation unit according to an embodiment; and

FIGS. 10(a) and (b) are each a diagram illustrating an example of installation of a thermoelectric power generation device having a reflector.

### DETAILED DESCRIPTION

The following describes the disclosed technique in detail.

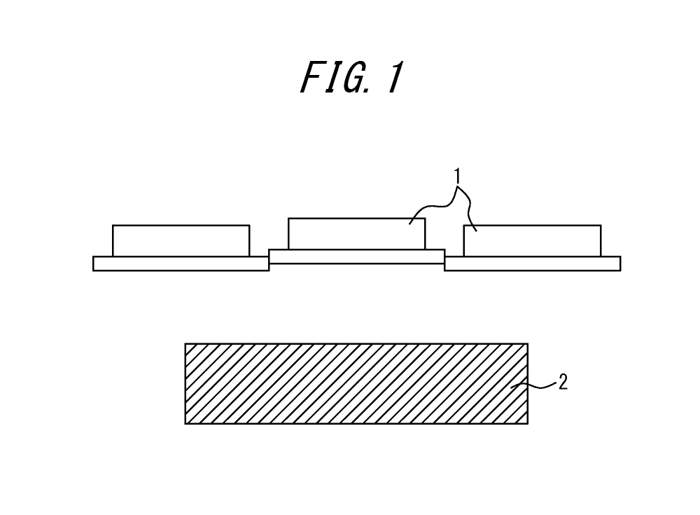

FIG. 1 is a schematic diagram for describing an embodiment of the disclosed thermoelectric power generation device. In the drawing, reference sign 1 is a thermoelectric power generation unit, and 2 is a steel material (heat source).

The thermoelectric power generation device includes the thermoelectric power generation unit 1 installed to face the steel material 2 and depending on the output of the thermoelectric power generation unit.

The steel material is not particularly limited as long as it is heated in a steelworks, a processing plant, or the like to a temperature of about 600° C. to 1300° C. Preferable examples include a hot slab in a continuous caster, a slab, a rough bar, and a hot-rolled steel strip in a hot rolling device, a sheet material and a pipe or tube material in a forge welded pipe or tube facility, and other bar steels such as a steel pipe or tube, a steel bar, a wire rod, and a rail (hereafter simply referred to as “steel material”).

The thermoelectric power generation device includes at least one thermoelectric power generation unit in the width direction and length direction of the steel material.

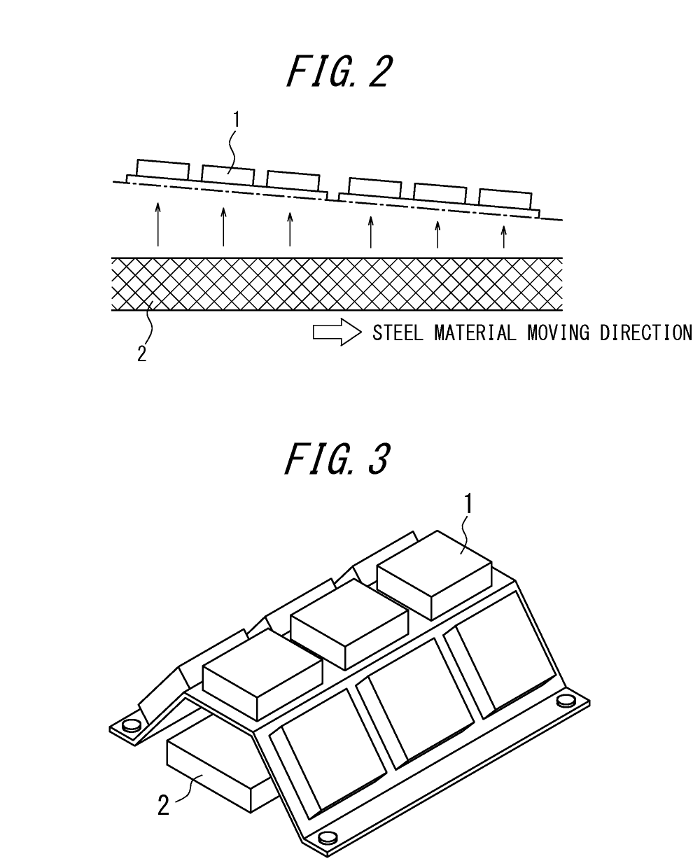

In detail, the thermoelectric power generation units may be arranged in the length direction of the steel material, as illustrated in FIGS. 2 and 3. The thermoelectric power generation units may be installed to be inclined toward the steel material in the steel material moving direction (the direction in which the temperature of the steel material decreases), as illustrated in FIG. 2. The thermoelectric power generation units may be installed on a plurality of sides, as illustrated in FIG. 3.

The thermoelectric power generation unit includes: a heat receiver facing the steel material; at least one thermoelectric power generation module;

and a heat releaser as described below.

The heat receiver reaches several degrees to several tens of degrees higher than the high temperature side of the thermoelectric element and, in some cases, reaches about several hundreds of degrees higher than the high temperature side of the thermoelectric element, depending on the material.

The heat receiver is accordingly made of any material having heat resistance and durability at the temperature. For example, copper, a copper alloy, aluminum, an aluminum alloy, ceramics, carbon, and other typical iron and steel materials may be used as the heat receiver.

The heat releaser may be conventionally known means. Though the heat releaser is not particularly limited, preferable examples include: a cooling device equipped with a fin; a water-cooling device utilizing contact heat transfer; a heat sink utilizing boiling heat transfer; and a water-cooling sheet having a refrigerant passage.

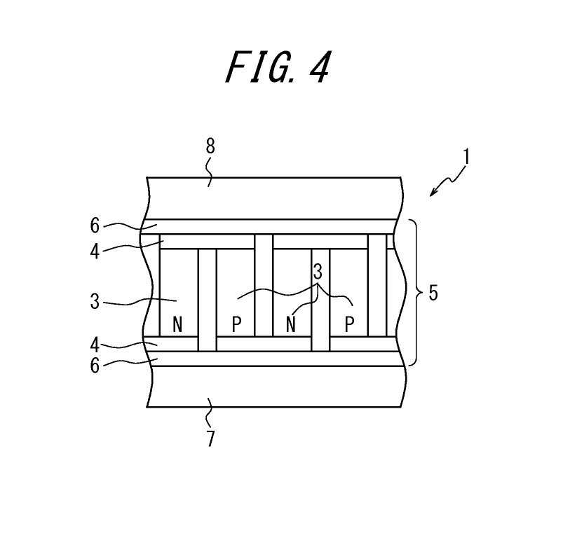

A thermoelectric power generation module 5 includes: a two-dimensionally arranged thermoelectric element group in which p-type and n-type semiconductors as thermoelectric elements 3 are connected by several tens to several thousands of pairs of electrodes; and an insulator 6 placed on both sides of the thermoelectric element group, as illustrated in FIG. 4. The thermoelectric power generation module 5 may also have a heat conductive sheet or a protection sheet on one or both sides. The respective protection sheets may also serve as a heat receiver 7 and a heat releaser 8.

In the case where the cooling sheet which is the heat receiver and/or the heat releaser is an insulator or is coated with an insulator on its surface, the cooling sheet may substitute for the insulator. The thermoelectric power generation unit 1 according to this embodiment includes the thermoelectric power generation module(s), and the heat receiver 7 and the heat releaser 8 provided on the outer sides of the thermoelectric power generation module(s).

The above-mentioned heat conductive sheet may be provided, for example, between the heat receiver and the thermoelectric power generation module, between the heat releaser and the thermoelectric power generation module, and between the insulator and the protection sheet, in order to reduce the heat contact resistance between the members and further improve the thermoelectric power generation efficiency. The heat conductive sheet has predetermined heat conductivity. The heat conductive sheet is not particularly limited as long as it can be used in the use environments of the thermoelectric power generation module. Examples of the heat conductive sheet include a graphite sheet.

The size of the thermoelectric power generation module is preferably not greater than 1×10⁻² m². When the size of the module is approximately in this range, the thermoelectric power generation module can be kept from deformation. The size of the thermoelectric power generation module is more preferably not greater than 2.5×10⁻³ m².

The size of the thermoelectric power generation unit is preferably not greater than 1 m². When the size of the thermoelectric power generation unit is not greater than 1 m², the deformation between the thermoelectric power generation modules and the deformation of the thermoelectric power generation unit itself can be suppressed. The size of the thermoelectric power generation unit is more preferably not greater than 2.5×10⁻¹ m².

The thermoelectric power generation device includes the thermoelectric power generation unit that is installed to face the steel material and depending on the output of the thermoelectric power generation unit.

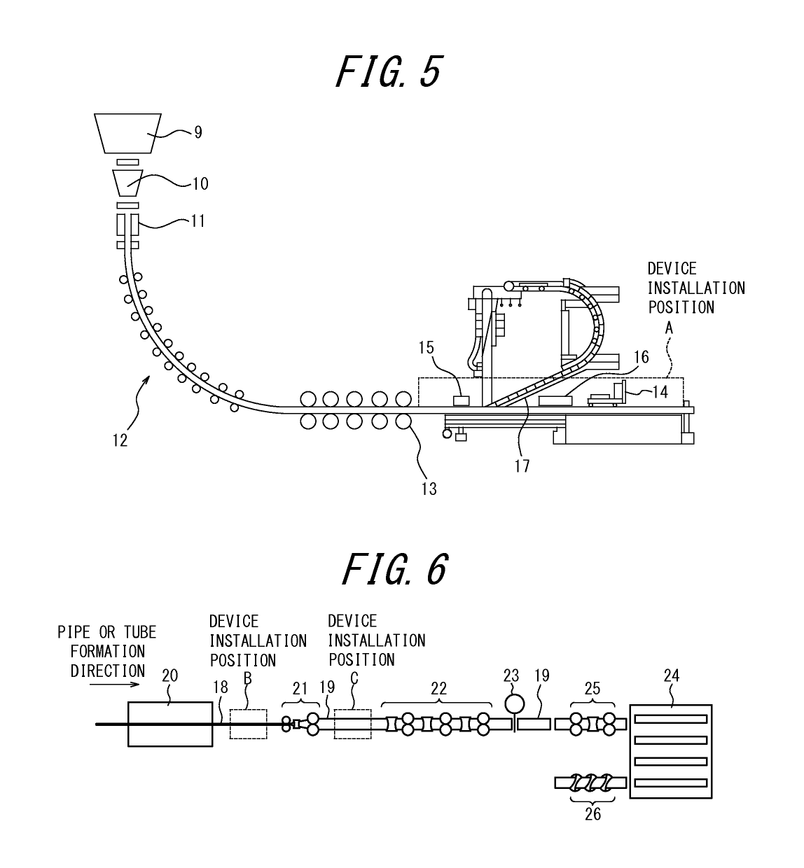

By installing, depending on the temperature of the steel material, such a thermoelectric power generation unit in: any position (A in FIG. 5) of upstream of a slab cutting device 14 in a continuous casting device, the underside of the slab cutting device, and the exit side of the slab cutting device as illustrated in FIG. 5; or any position of a steel sheet conveyance path from a heating furnace to a forming machine/forge welder and a pipe or tube material conveyance path (B and C in FIG. 6) in a forge welded pipe or tube line as illustrated in FIG. 6, efficient power generation can be performed in response to, for example, the temperature variations of the heat source in actual operation. In FIG. 5, reference sign 9 is a ladle, 10 is a tundish, 11 is a mold, 12 is a slab cooling device, 13 is a roller group such as straightening rolls, 14 is a slab cutting device, 15 is a thermometer, 16 is a thermoelectric power generation device, and 17 is a dummy bar table. In FIG. 6, reference sign 18 is a steel sheet, 19 is a pipe or tube material, 20 is a heating furnace, 21 is a forming machine/forge welder, 22 is a hot reducer, 23 is a rotary hot saw, 24 is a cooling bed, 25 is a sizer, and 26 is a straightener.

Moreover, attaching the thermoelectric power generation unit to the underside of the dummy bar table 17 for recovering a slab for adjustment is preferable in terms of avoiding an increase of the number of components in the facility.

Since the temperature of the steel material is the same to a certain extent according to the size or type, the installation position of the thermoelectric power generation unit may be set beforehand depending on the size or type. The installation position of the thermoelectric power generation unit may be set beforehand depending on the size or type, from not only the output power track records for each thermoelectric power generation unit but also the output power prediction values based on the temperature of the steel material and the like. In addition, the distance between the thermoelectric power generation unit and the steel material as the heat source and the arrangement of the thermoelectric power generation modules in the thermoelectric power generation unit may be determined upon facility introduction.

The thermoelectric power generation device (thermoelectric power generation unit) may be installed not only above the steel material but below or on the side of the steel material. The thermoelectric power generation device (thermoelectric power generation unit) may be installed not only in one position but in a plurality of positions.

The thermometer 15 may be installed on the upstream side of the thermoelectric power generation device 16 as illustrated in FIG. 5, so that the distance between the thermoelectric power generation unit and the steel material can be controlled depending on the measurement of the thermometer. For example, even in the case where the temperature of the steel material varies due to a production lot change or the like, such a function enables thermoelectric power generation to be performed appropriately in response to the temperature variation or the like, thus further improving the thermoelectric power generation efficiency.

The thermometer is preferably a contactless thermometer such as a radiation thermometer. In the case where the line stops intermittently, however, a thermocouple may be brought into contact for measurement each time the line stops. As the measurement frequency, it is desirable to install the thermometer in the line and automatically measure the temperature on a regular basis, though an operator may manually measure the temperature in the case where the manufacturing conditions are changed.

If the relationship between the temperature of the steel material and the distance corresponding to the most efficient thermoelectric power generation is determined beforehand, the distance between the thermoelectric power generation unit and the steel material can be appropriately controlled in response to temperature variations depending on the measurement of the thermometer.

A key feature of the disclosure is that the installation is performed depending on the output of the thermoelectric power generation unit resulting from the temperature difference between the thermoelectric power generation unit and the steel material. In detail, the distance between the thermoelectric power generation unit and the steel material as the heat source is adjusted to increase the power output. An actually measured output or an output value predicted from, for example, the temperature of the steel material or the thermoelectric power generation unit may be used when adjusting the distance.

In the case of installing the thermoelectric power generation unit to face the steel material, the distance between the heat source and the thermoelectric power generation unit is not particularly limited, though the range of about 10 mm to 1000 mm is preferable.

As an example, efficient thermoelectric power generation can be performed by setting the distance between the thermoelectric power generation unit in which 50 mm square thermoelectric power generation modules are arranged at intervals of 70 mm and the hot slab to 340 mm in the case where the temperature of the hot slab in the continuous caster is 950° C., and to 160 mm in the case where the temperature of the hot slab is 900° C.

As another example, the most efficient thermoelectric power generation can be performed by setting the distance between the thermoelectric power generation unit in which 50 mm square thermoelectric power generation modules are arranged at intervals of 80 mm and the pipe or tube material, etc. to 150 mm in the case where the temperature of the pipe or tube material in the forge welded pipe or tube facility is 1150° C., and to 60 mm in the case where the temperature of the pipe or tube material is 1000° C.

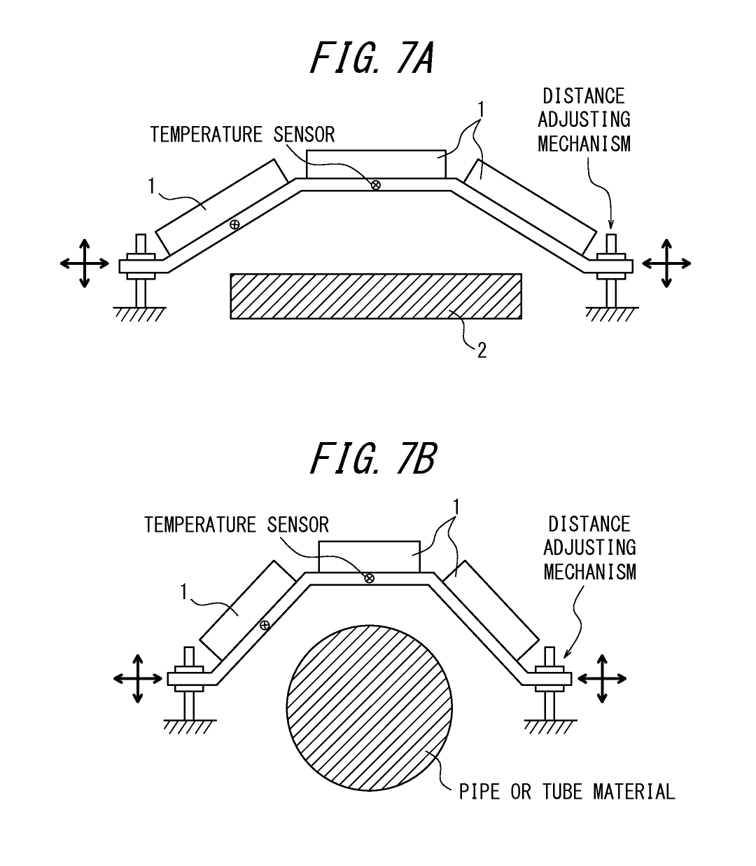

As illustrated in FIGS. 7(a) and (b), a distance adjusting mechanism which is distance adjusting means and is capable of movement in two independent directions of the vertical direction and the lateral direction and a temperature sensor may be attached to the thermoelectric power generation unit to monitor whether or not the thermoelectric power generation unit receiving heat from the steel material or the pipe or tube material is within an optimal temperature range (250° C. to 280° C.) and, in the case where the thermoelectric power generation unit is not within the optimal temperature range, manually or automatically adjust the distance between the steel material and the thermoelectric power generation unit using the distance adjusting mechanism capable of movement in two independent directions of the vertical direction and the lateral direction. Thus, the thermoelectric power generation unit may be installed depending on the temperature and shape of the steel material and the temperature of the atmosphere (the position at which the thermoelectric power generation unit faces the steel material, the position suitable for temperature measurement, and the vicinity thereof).

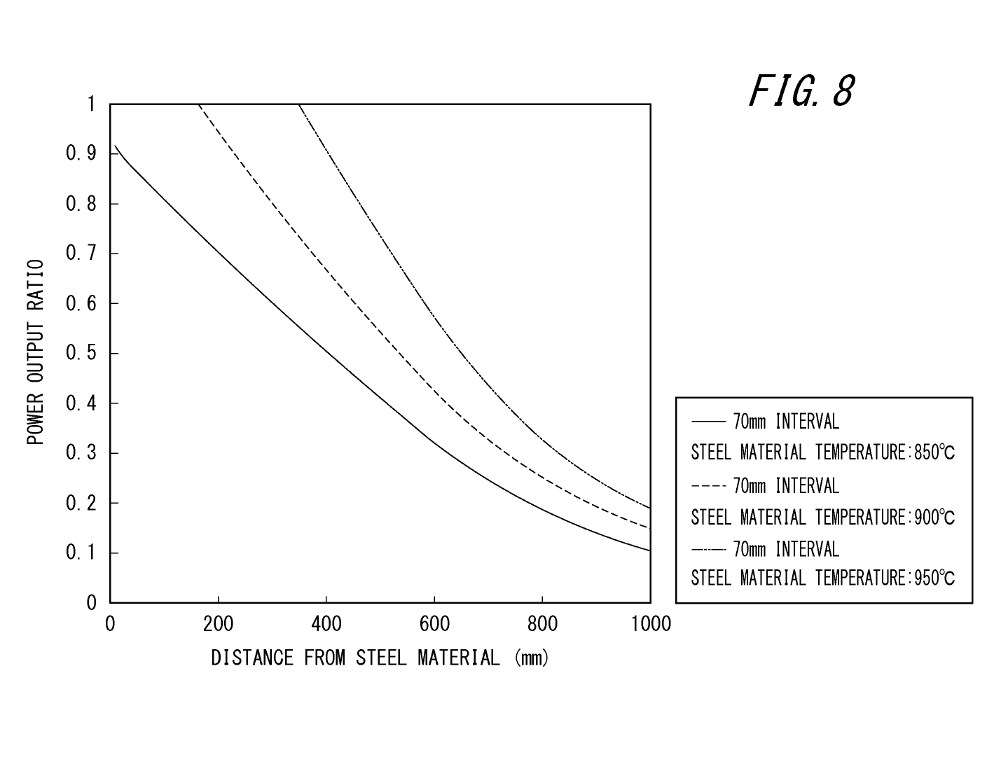

FIG. 8 illustrates the relationship between the distance from the steel material to the thermoelectric power generation unit and the power output ratio where the power output ratio at the rated output is 1, as a result of conducting study with the thermoelectric power generation module interval in the thermoelectric power generation unit and the temperature of the steel material as parameters. Such a relationship is obtained to adjust the distance between the thermoelectric power generation unit and the steel material as the heat source or the arrangement of the thermoelectric power generation modules in the thermoelectric power generation unit so as to increase the output of the thermoelectric power generation unit. An actually measured output or an output value predicted from, for example, the temperature of the steel material may be used here.

The output of the thermoelectric power generation unit is preferably set to the rated output as mentioned above. Here, the setting needs to be performed in consideration of the upper limit of the heat resistance temperature of the thermoelectric power generation unit so as not to break the thermoelectric element. In the case of taking the upper limit of the heat resistance temperature into consideration, the target power output ratio may be decreased optionally. The decrease of the target power output ratio is preferably up to about 0.7.

In the thermoelectric power generation device, the thermoelectric power generation unit is preferably installed nearer the steel material in the low temperature portion with low output than in the high temperature portion with high output, depending on the output of the thermoelectric power generation unit. Such a device is particularly suitable for a continuous line where the temperature changes little. Since it is possible to measure the temperature distribution of the steel material in the width direction (the direction perpendicular to the travel direction of the steel material) beforehand and reflect the measurement in the above-mentioned distance, the power generation efficiency of the thermoelectric power generation unit can be optimized as compared with the case where the thermoelectric power generation unit is simply installed flat.

Thus, the relationship between the output of the thermoelectric power generation unit and the distance between the thermoelectric power generation unit and the steel material corresponding to the most efficient thermoelectric power generation is determined beforehand, and the thermoelectric power generation unit is installed away from the steel material in the center portion of the steel material, i.e. the high temperature portion with high output, and the thermoelectric power generation unit in the width direction is installed near the steel material in the end portion of the steel material, i.e. the low temperature portion with low output. This enables each individual thermoelectric power generation unit to perform efficient thermoelectric power generation.

For example, efficient thermoelectric power generation can be performed by setting the distance between the thermoelectric power generation unit 1 and the steel material 2 to 340 mm in the center portion of the steel material 2 and to 160 mm in the end portion of the steel material 2 in FIG. 1.

The temperature distribution of the steel material in the width direction tends to sharply decrease at the position corresponding to about the sheet thickness to twice the sheet thickness of the steel material. It is therefore preferable to control the distance between the thermoelectric power generation unit and the steel material as mentioned above, especially in the end portion of the steel material corresponding to about the sheet thickness to twice the sheet thickness of the steel material.

The end portion of the steel material is typically low in temperature. In the embodiment as illustrated in FIG. 1, the shape of installation of the thermoelectric power generation unit may be a half ellipse form. This provides the advantageous effect of enclosing the heat source, and has the feature of excellent heat insulation effect as the behavior of the heat flow changes. The thermoelectric power generation device thus exhibits excellent heat energy recovery effect.

When means for controlling the distance between the thermoelectric power generation unit and the steel material is added to this embodiment, the thermoelectric power generation device can generate power more efficiently by appropriately controlling the distance between the thermoelectric power generation unit and the steel material, for example even in the case where the temperature of the heat source varies in actual operation.

In the thermoelectric power generation device, the arrangement density of the thermoelectric power generation modules or thermoelectric elements in the thermoelectric power generation unit may be higher in the high temperature portion with high output than in the low temperature portion with low output, depending on the output of the thermoelectric power generation unit. Such arrangement is also suitable for a continuous line where the temperature changes little. Since it is possible to measure the temperature distribution of the steel material in the width direction (the direction perpendicular to the travel direction of the steel material) beforehand and reflect the measurement in the above-mentioned arrangement density, the power generation efficiency of the thermoelectric power generation unit can be further improved as compared with the case where the thermoelectric power generation units are simply installed at fixed intervals.

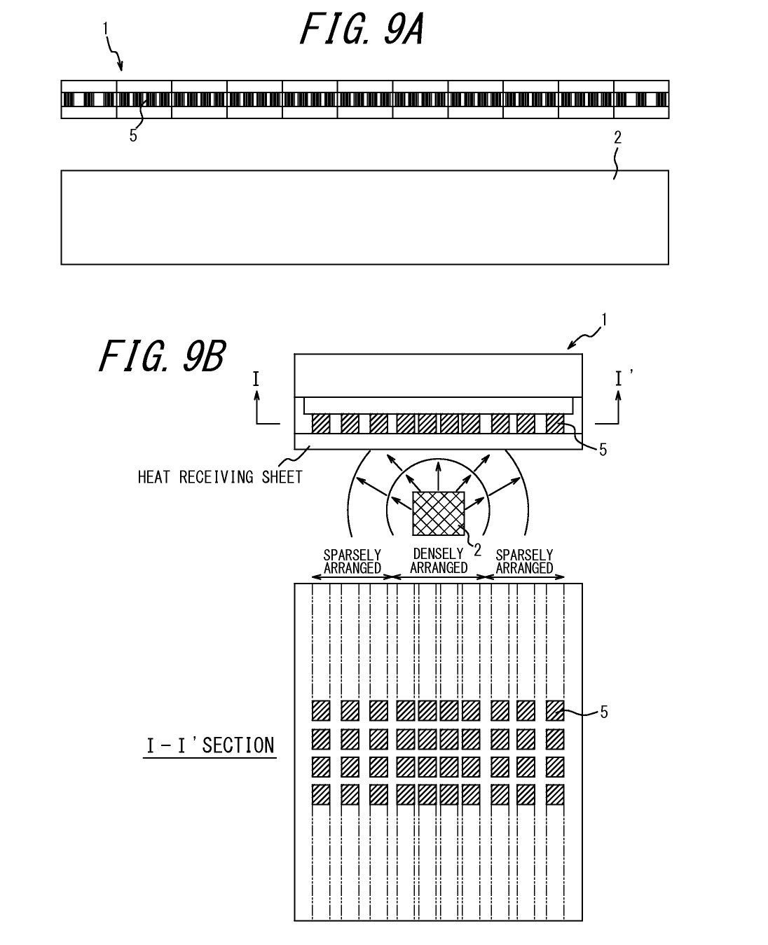

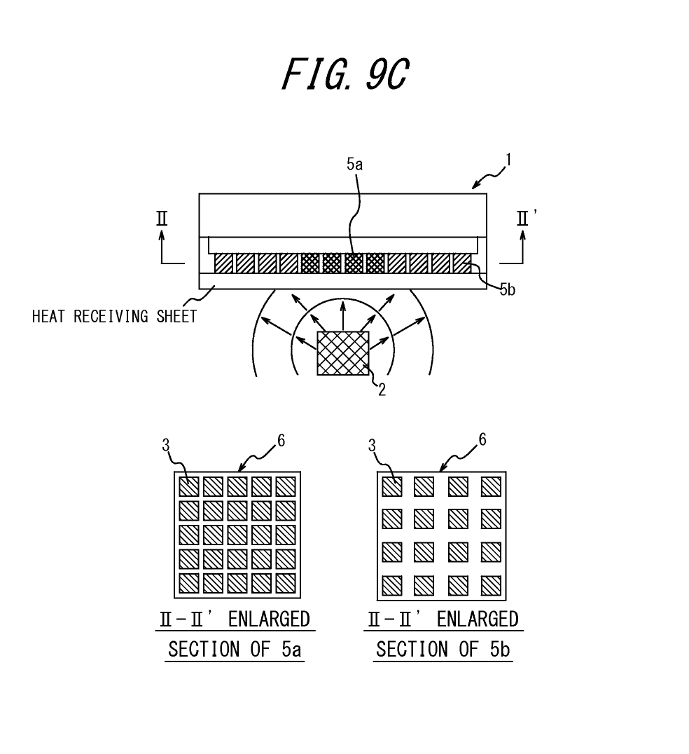

As illustrated in FIGS. 9A to 9C, thermoelectric power generation modules 5 in the thermoelectric power generation unit 1 are densely arranged or a thermoelectric power generation module 5a in which thermoelectric elements are densely arranged is arranged in the portion directly above the steel material 2, i.e. the high temperature portion with high output, and thermoelectric power generation modules 5 in the thermoelectric power generation unit 1 in the width direction are sparsely arranged or a thermoelectric power generation module 5b in which thermoelectric elements are sparsely arranged is arranged in the end portion of the steel material 2, i.e. the low temperature portion with low output. The thermoelectric power generation device with effectively improved power generation efficiency of each individual thermoelectric power generation unit 1 can thus be realized.

For example, efficient thermoelectric power generation can be performed by arranging the thermoelectric power generation modules 5 at intervals of 70 mm in the center portion of the thermoelectric power generation unit and at intervals of 78 mm in the end portion. The optimal interval of thermoelectric power generation modules may be studied and set using the thermoelectric power generation module interval in the thermoelectric power generation unit illustrated in FIG. 8 as a parameter.

Furthermore, in the embodiment in which the arrangement density of thermoelectric power generation modules or thermoelectric elements is changed, the arrangement of thermoelectric power generation modules or thermoelectric elements in each thermoelectric power generation unit may be varied in density, or the arrangement of thermoelectric power generation units may be varied in density.

The embodiment in which the arrangement density of thermoelectric power generation modules or thermoelectric elements is changed is particularly suitable in the case where there is no installation tolerance of the facility in the direction above the steel material but there is an installation tolerance in the lateral direction. The means for controlling the distance between the thermoelectric power generation unit and the steel material may be added to this embodiment, too. Hence, the thermoelectric power generation device can generate power more efficiently by appropriately controlling the distance between the thermoelectric power generation unit and the steel material even in the case of, for example, the temperature variations of the heat source in actual operation.

The expression “depending on the output of the thermoelectric power generation unit” includes changing the position of the thermoelectric power generation unit or the arrangement density of thermoelectric power generation modules or thermoelectric elements according to the temperature of the steel material. In addition, the expression also includes the following measure: in the case where there is an output difference between thermoelectric power generation units when, for example, the thermoelectric power generation units are installed at an initial position, a thermoelectric power generation unit with low output is moved to increase the output, i.e. installed nearer the steel material. The expression “depending on the temperature” does not only simply mean “based on the temperature of the steel material” but also means “based on the temperature distribution and/or configuration factor of the steel material”.

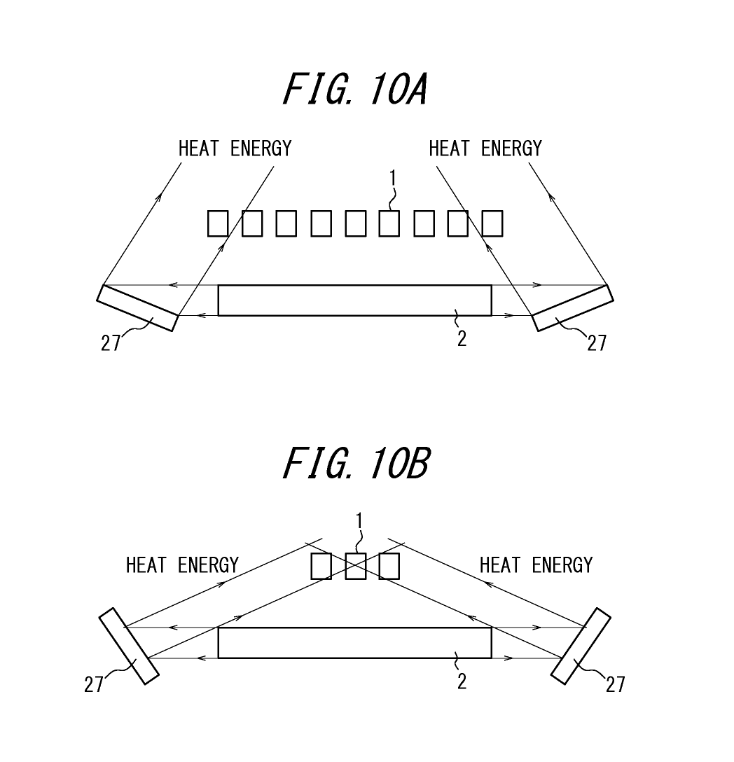

The thermoelectric power generation device may further include a heat reflector for collecting heat, as illustrated in FIGS. 10(a) and (b). In the drawing, reference sign 27 is a heat reflector, and 1 is a thermoelectric power generation unit. The use of such a heat reflector 27 enhances the heat collection efficiency for each individual thermoelectric power generation unit, and enables more efficient thermoelectric power generation.

The heat reflector is preferably installed on both sides of the steel material 2 as illustrated in FIG. 10(a) (in the drawing, the travel direction of the steel material is from back to front of the drawing), for heat collection efficiency.

For example, by collecting heat at the thermoelectric power generation units 1 with favorable balance as illustrated in FIG. 10(a), the power generation efficiency of the individual thermoelectric power generation units can be further improved even when the thermoelectric power generation units are in ordinary flat arrangement in the thermoelectric power generation device. Furthermore, heat energy collected at any part may be applied to the thermoelectric power generation units 1, as illustrated in FIG. 10(b). The advantage of this embodiment lies in that, even in the case where the installation area of the thermoelectric power generation units is limited, in the case where thermoelectric power generation units having a desired area are not available, or in the case where the thermoelectric power generation unit cannot be moved up and down, efficient thermoelectric power generation can be performed by moving the heat reflector 27 appropriately. A drive unit may be provided for the heat reflector 27 so that the heat collection part can be changed by changing the angle according to an external signal.

While the heat reflector 27 is installed on both sides of the steel material 2 in FIGS. 10(a) and (b), the heat reflector may be installed above and below the steel material depending on the installation position of the thermoelectric power generation unit.

The cross-section of the heat reflector may be flat, curved, V-shaped, or U-shaped. The heat reflector favorably has a surface that ranges from flat to concave. Here, since the aberration at the focal point changes depending on the angle of incidence on the concave heat reflector, it is preferable to install one heat reflector or a group of a plurality of heat reflector surfaces so as to assume an optimal heat reflector shape (curvature) that minimizes the aberration for a predetermined angle of incidence.

The heat reflector may also serve as a heat insulation board. Alternatively, a heat insulation board may be installed outside the heat reflector so as to cover the heat reflector.

Though the above-mentioned FIG. 10 does not illustrate a separately installed heat insulation board, the heat insulation board may cover the entire reflector or have an opening at the installation position of the thermoelectric power generation unit and the reflector.

In the embodiment in which the heat reflector is used, heat can be collected at any part of the thermoelectric power generation units. This has the advantage of further improving the installation tolerance of the thermoelectric power generation device, as explained below.

The heat reflector is not particularly limited as long as it can reflect heat energy (infrared radiation). A mirrored metal such as iron, a tinned heat-resistant tile, or the like may be selected as appropriate in consideration of the installation position, the ease of material procurement, etc.

Thus, the thermoelectric power generation unit installed depending on at least one of the temperature of the steel material and the temperature and output of the thermoelectric power generation unit includes not only the thermoelectric power generation unit for which the distance is set but also the thermoelectric power generation unit for which the distance or the angle can be changed by the heat reflector.

In the case of installing the thermoelectric power generation unit on the side of or below the steel material, the installation is preferably performed so as to satisfy the relationship ds≦du in consideration of the influence of heat convection from the steel material, where ds is the distance between the thermoelectric power generation device and the steel material on the side or lower surface and du is the distance between the thermoelectric power generation device and the steel material on the upper surface. Note that the distance between the heat source and each thermoelectric power generation unit may be varied as appropriate within the same device.

In the case where the thermoelectric power generation units are not installed for all surfaces, a board (heat insulation board) may be installed to prevent the heat of the heat source from escaping outside, thus enabling efficient thermoelectric power generation. The material of the heat insulation board is not particularly limited as long as it is typically used as a heat insulation board of a high temperature object and can resist the temperature of the installation position, e.g. a metal (alloy) such as iron or Inconel, ceramics, etc. The board preferably has low emissivity to reduce the amount of radiant heat, which is generated from the heat source, absorbed by the board so that the heat is transmitted toward the thermoelectric power generation unit.

The thermoelectric power generation device may include the transporter for moving the thermoelectric power generation unit.

The distance between the thermoelectric power generation unit and the slab, etc. can be controlled using the transporter. The distance is preferably controlled using a power cylinder.

The transporter is capable of moving the thermoelectric power generation unit up and down. The transporter capable of moving the thermoelectric power generation unit back and forth and/or right and left can also be used without any particular problem.

The thermoelectric power generation device may include a plurality of thermoelectric power generation units. In the case where a plurality of thermoelectric power generation are included, at least one of the thermoelectric power generation units may include the transporter.

The transporter may be a distance controller for monitoring at least one of the temperature of the steel material and the temperature and output of the thermoelectric power generation unit and controlling the distance between the thermoelectric power generation unit and the steel material depending on the monitored temperature and/or output.

Through the use of the above-mentioned transporter, the thermoelectric power generation unit can be moved from the power generation region to the retraction position to prevent the device from breakage caused by, for example, the variation in height of the steel material in a non-steady state upon operation start or end, and then moved back to the power generation region.

The embodiments described above may be freely combined. For example, when the thermoelectric power generation units are installed in the form of an elliptic arc with an extremely large curvature in the case of attempting to achieve optimal thermoelectric power generation efficiency only by distance adjustment, the embodiment of using the heat reflector may be combined to alleviate the curvature.

The thermoelectric power generation device may include all embodiments simultaneously.

The disclosed thermoelectric power generation method converts heat energy radiated from a steel material into electric energy. Thus, for example in the manufacturing line illustrated in any of FIGS. 5 and 6, as a requirement the thermoelectric power generation unit of the thermoelectric power generation device illustrated in any of FIGS. 1 to 3, 7, 9, and 10 is installed depending on the temperature and/or output of the thermoelectric power generation unit, which may be combined with any of the following structures: the thermoelectric power generation unit is installed depending on the temperature of the steel material; the thermoelectric power generation unit is installed nearer the steel material in the low temperature portion with low output than in the high temperature portion with high output depending on the temperature and/or output of the thermoelectric power generation unit; the thermoelectric power generation modules or thermoelectric elements in the thermoelectric power generation unit are arranged more densely in the high temperature portion with high output than in the low temperature portion with low output depending on at least one of the temperature of the steel material and the temperature and output of the thermoelectric power generation unit; the heat reflector is provided; and the transporter capable of moving the thermoelectric power generation unit is included. The transporter may be a distance controller for monitoring at least one of the temperature of the steel material and the temperature and output of the thermoelectric power generation unit and controlling the distance between the thermoelectric power generation unit and the steel material depending on the monitored temperature and/or output.

When implementing the thermoelectric power generation method, the thermoelectric power generation devices according to the plurality of embodiments described above may be used in combination.

### Examples

To confirm the advantageous effects of the disclosed thermoelectric power generation device, the following test was conducted. In a thermoelectric power generation device having an area of about 1 m² above a slab, thermoelectric power generation units were installed at the position A in FIG. 5, and the output of each thermoelectric power generation unit was examined. The hot slab (hereafter simply referred to as “slab”) was 900 mm in width and 250 mm in thickness.

In Example 1, the temperature of the slab was 950° C., 50 mm square thermoelectric power generation modules were arranged at intervals of 80 mm in the thermoelectric power generation unit, and the distance to the slab was set to 495 mm to produce substantially the rated output in most parts in the width direction.

As a result, the output was substantially the rated output in most parts in the width direction. The output in the width end was 81%. The temperature of the steel sheet in the width end was 908° C.

In Example 2, the temperature of the slab was 850° C., 50 mm square thermoelectric power generation modules were arranged at intervals of 80 mm in the thermoelectric power generation unit, and the distance to the slab was set to 220 mm to produce substantially the rated output in most parts in the width direction. As a result, the output was substantially the rated output in most parts in the width direction. The output in the width end portion (the range of approximately 80 mm or less from the width end, hereafter referred to as “end portion”) was about 83%. The temperature of the steel sheet in the end portion was 825° C.

In Example 3, the temperature of the slab was 950° C., 50 mm square thermoelectric power generation modules were arranged at intervals of 80 mm in the thermoelectric power generation unit, and the distance between the thermoelectric power generation unit and the steel material was set to 495 mm in the center portion and 400 mm in the end portion to produce substantially the rated output across the full width. As a result, the output was substantially the rated output across the full width. The temperature of the steel sheet in the end portion was 908° C.

In Example 4, the temperature of the slab was 850° C., 50 mm square thermoelectric power generation modules were arranged at intervals of 80 mm in the thermoelectric power generation unit, and the distance between the thermoelectric power generation unit and the steel material was set to 220 mm in the center portion and 100 mm in the end portion to produce substantially the rated output across the full width.

As a result, the output was substantially the rated output across the full width. The temperature of the steel sheet in the end portion was 825° C.

In Example 5, the temperature of the slab was 950° C., the distance between the thermoelectric power generation unit and the steel material was set to 495 mm to produce substantially the rated output across the full width, and thermoelectric power generation modules were arranged at intervals of 80 mm in the center portion and at intervals of 90 mm in the end portion of the thermoelectric power generation unit.

As a result, the output was substantially the rated output across the full width. The temperature of the steel sheet in the end portion was 908° C.

In Example 6, the temperature of the slab was 950° C., the distance between the thermoelectric power generation unit and the steel material was set to 400 mm to produce substantially the rated output across the full width, and thermoelectric power generation modules were arranged at intervals of 73 mm in the center portion and at intervals of 80 mm in the end portion of the thermoelectric power generation unit.

As a result, the output was substantially the rated output across the full width. Since the number of thermoelectric power generation modules increased from 168 to 184, the total output was 1.2 times higher. The temperature of the steel sheet in the end portion was 908° C.

In Example 7, the structure illustrated in FIG. 10(a) was employed to produce substantially the rated output across the full width, with the heat reflector for collecting heat at the thermoelectric power generation unit being disposed. The slab having the same temperature distribution as that in Example 1 was used here.

As a result, substantially the rated output was obtained by the thermoelectric power generation unit.

In Comparative Example, in the case where the temperature of the slab was 950° C., the distance between the thermoelectric power generation unit in which 50 mm square thermoelectric power generation modules were arranged at intervals of 60 mm and the slab was set to 495 mm. As a result, the output was only 42% of the rated output in the end portion and 53% of the rated output in the other parts in the width direction.

In Example 9, in the case where the temperature of the slab was 950° C., the distance between the thermoelectric power generation unit in which 50 mm square thermoelectric power generation modules were arranged at intervals of 60 mm and the slab was changed to 100 mm upon reaching the stable conveyance state of the slab.

As a result, the output was 92% of the rated output in the end portion, and the rated output in the other parts in the width direction. Substantially the same results were obtained in the case of installing the thermoelectric power generation unit depending on the temperature of the thermoelectric power generation unit.

Though the installation position of the thermoelectric power generation unit was set depending on the temperature of the steel material (slab) in the continuous casting line in the foregoing Examples, the same results were confirmed even when adding any of the following embodiments: installing the thermoelectric power generation unit depending on the temperature of any other steel material such as a rough bar or a hot-rolled steel strip or a sheet material or a pipe or tube material in a forge welded pipe or tube facility; installing the thermoelectric power generation unit depending on the output of the thermoelectric power generation unit; and changing the installation position.

### INDUSTRIAL APPLICABILITY

Heat generated from a steel material can be effectively converted into electric power, which contributes to energy saving in manufacturing plants.

### REFERENCE SIGNS LIST

1 thermoelectric power generation unit

2 steel material

3 thermoelectric element

4 electrode

5, 5a, 5b thermoelectric power generation module

6 insulator

7 heat receiver

8 heat releaser

9 ladle

10 tundish

11 mold

12 slab cooling device

13 roller group such as straightening rolls

14 slab cutting device

15 thermometer

16 thermoelectric power generation device

17 dummy bar table

18 steel sheet

19 pipe or tube material

20 heating furnace

21 forming machine/forge welder

22 hot reducer

23 rotary hot saw

24 cooling bed

25 sizer

26 straightener

27 heat reflector

1. A thermoelectric power generation device comprising
a thermoelectric power generation unit that converts heat energy radiated from a steel material into electric energy,
wherein the thermoelectric power generation unit is installed to face the steel material and depending on an output of the thermoelectric power generation unit.

2. The thermoelectric power generation device according to claim 1,
wherein the thermoelectric power generation unit is installed nearer the steel material in a low temperature portion with low output than in a high temperature portion with high output, depending on the output of the thermoelectric power generation unit.

3. The thermoelectric power generation device according to claim 1,
wherein one or more thermoelectric power generation modules or thermoelectric elements in the thermoelectric power generation unit are arranged more densely in a high temperature portion with high output than in a low temperature portion with low output, depending on the output of the thermoelectric power generation unit.

4. The thermoelectric power generation device according to claim 1, comprising
a heat reflector.

5. The thermoelectric power generation device according to claim 1,
wherein the thermoelectric power generation unit is installed further depending on at least one of a temperature of the thermoelectric power generation unit and a temperature of the steel material.

6. The thermoelectric power generation device according to claim 1, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

7. The thermoelectric power generation device according to claim 1, comprising
a transporter for moving the thermoelectric power generation unit.

8. A thermoelectric power generation method of receiving heat of a steel material and performing thermoelectric power generation, using the thermoelectric power generation device according to claim 1.

9. The thermoelectric power generation device according to claim 2,
wherein one or more thermoelectric power generation modules or thermoelectric elements in the thermoelectric power generation unit are arranged more densely in a high temperature portion with high output than in a low temperature portion with low output, depending on the output of the thermoelectric power generation unit.

10. The thermoelectric power generation device according to claim 2,
wherein the thermoelectric power generation unit is installed further depending on at least one of a temperature of the thermoelectric power generation unit and a temperature of the steel material.

11. The thermoelectric power generation device according to claim 3,
wherein the thermoelectric power generation unit is installed further depending on at least one of a temperature of the thermoelectric power generation unit and a temperature of the steel material.

12. The thermoelectric power generation device according to claim 9,
wherein the thermoelectric power generation unit is installed further depending on at least one of a temperature of the thermoelectric power generation unit and a temperature of the steel material.

13. The thermoelectric power generation device according to claim 2, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

14. The thermoelectric power generation device according to claim 3, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

15. The thermoelectric power generation device according to claim 5, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

16. The thermoelectric power generation device according to claim 9, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

17. The thermoelectric power generation device according to claim 11, comprising
a distance controller for monitoring at least one of: a temperature of the steel material; a temperature of the thermoelectric power generation unit; and the output of the thermoelectric power generation unit, and controlling a distance between the thermoelectric power generation unit and the steel material depending on the monitored at least one of the temperatures and the output.

18. The thermoelectric power generation device according to claim 3, comprising
a transporter for moving the thermoelectric power generation unit.

19. The thermoelectric power generation device according to claim 14, comprising
a transporter for moving the thermoelectric power generation unit.

20. A thermoelectric power generation method of receiving heat of a steel material and performing thermoelectric power generation, using the thermoelectric power generation device according to claim 3.
